(19) United States
(12) Patent Application Publication
(10) Pub. No.: US 2025/0293644 A1
(43) Pub. Date: Sep. 18, 2025

(54) DUAL PRIMARY MULTI-COUPLED OUTPUT AMPLIFIER ARCHITECTURE

(71) Applicant: Steven M. Fryette, Valley Glen, CA (US)

(72) Inventor: Steven M. Fryette, Valley Glen, CA (US)

(21) Appl. No.: 19/082,096

(22) Filed: Mar. 17, 2025

Related U.S. Application Data
(60) Provisional application No. 63/566,363, filed on Mar. 17, 2024.
(60) Provisional application No. 63/566,604, filed on Mar. 18, 2024.

(51) Int. Cl. H03F 3/181; H03F 1/56

(52) U.S. Cl. CPC H03F 3/181; H03F 1/56; H03F 2200/03; H03F 2200/222; H03F 2200/387

(57) ABSTRACT

An audio amplifier system of first and second audio power stages driven and biased by power stage drive subsystem, which operates dissimilar power output stages to cause the generation of first and second dissimilar sets of audio characteristics at an output transformer of twin primaries. The loss of power in one power stage does not alter the biasing and output in the other power stage, such that the other power stage remains operable and impedance matched.

### BACKGROUND

For the past several decades tube amplifier manufacturers have experimented with using dissimilar power tubes together to try to capture or combine the characteristics of different power tube types. For example, one vendor markets the ability to switch tube types to achieve a mix of the desired overall amplifier effects, as well as combining different classes of tube operation (e.g., Class A, AB, etc.) to capture the nuances of the various topologies.

However, different tube types exhibit impedance characteristics at different operating voltages and impedances, which can then introduce compromises in operating characteristics of the selected tubes which are less than ideal for the desired overall effect.

### SUMMARY

The following presents a simplified summary in order to provide a basic understanding of some novel embodiments described herein. This summary is not an extensive overview, and it is not intended to identify key/critical elements or to delineate the scope thereof. Its sole purpose is to present some concepts in a simplified form as a prelude to the more detailed description that is presented later.

The implementation of compromises in audio amplifier designs in the existing marketplace result in dissatisfied users due to the sale of amplifiers employing technical concessions in tube operating environments and output transformer power operation.

In contrast to existing systems in the marketplace where one standard output transformer cannot necessarily present an optimum load to each type of tube or operating class, the disclosed dual primary multi-coupled output audio amplifier architecture employs a technique which offers a power-tube combining scenario that avoids the conventional “power tube switching” narrative by “combining” power tube characteristics using dissimilar tubes that can be operated to co-exist with a single output transformer (of multiple (e.g., two) identical and isolated primary windings).

The output transformer can employ isolated primary windings (e.g., identical) of select turns ratios. A pair of power tubes can be connected to each primary winding. For example, each primary winding can be thirty-five hundred (3500) ohms with respect to a secondary impedance of sixteen (16) ohms. In one example implementation, utilizing a pair of KT88 tubes exhibits a plate-to-plate impedance of about 3,000 ohms to about 5,000 ohms (depending on a supply voltage of about 400V to about 600V).

Similar conditions can apply to a pair of tubes (e.g., EL34s), but on a different sliding scale. For example, consider there is a voltage range of about 430V to about 450V, where the pair of tube scales converge at about 3500 ohms. Thusly, operating one tube pair at about 430V causes the tube-pair curves to approach concurrence while blending the relative strengths of the tubes independently, via the isolated output transformer primaries.

The disclosed audio amplifier architecture can employ multiple power tubes (e.g., four KT88s, two EL34s and two KT88s, etc.). The KT88s are among the highest output tubes used in guitar amplifiers. Alternatively, where customers may want tubes (e.g., EL34s) that, in operation, sound less powerful, and exhibit a complex harmonic blend (when “driven hard”—into clipping (a form of distortion that occurs when an amplifier attempts to deliver voltage or current beyond its maximum capability)) that musicians find musical and rich.

As previously indicated, the different types of tubes, when “pushed” (at greater power) can behave somewhat differently; a characteristic that can provide a beneficial output or behavior. To expose this behavior, each pair of tubes can be coupled to the power stage drive subsystem (the driver stage for the power tubes) differently to optimize respective ideal bias points and at the same time maximize the different tube “personalities” (output characteristics). For example, by preventing too much low end (e.g., intentionally rolling off low frequencies below a specific threshold) from getting to the EL34s, the EL34s can be driven by the drive stage with altered low frequency coupling capabilities for the incoming signal, and in the range that EL34s provide optimum sonic blend relative to the behavior of the associated KT88 pair.

Accordingly, in one embodiment, there is provided a first audio power stage which outputs first audio output characteristics; a second audio power stage which outputs second audio output characteristics; a power stage drive subsystem which drives the first audio power stage to output the first audio output characteristics, and drives the second audio power stage to output the second audio output characteristics; and an audio output transformer, the first audio output characteristics and the second audio output characteristics output via primaries of the audio output transformer.

The power stage drive subsystem drives the first audio power stage to output the first audio output characteristics, which first audio output characteristics are inherent to first audio power components of the first audio power stage, and drives the second audio power stage to output the second audio output characteristics, which second audio output characteristics are inherent to second audio power components of the second audio power stage.

The inherent first audio output characteristics are output via a first primary of the audio output transformer, and the inherent second audio output characteristics are output via a second primary of the output transformer. The inherent first audio output characteristics can be different than the inherent second audio output characteristics.

The power stage drive subsystem can be configured for dissimilar coupling of the first audio power stage and the second audio power stage, wherein the first audio power stage operates on a bias voltage source different than a bias voltage source of the second audio power stage.

The audio output transformer is configured to output the inherent first audio output characteristics via a first primary of the audio output transformer, and configured to output the inherent second audio output characteristics via a second primary of the audio output transformer.

The audio amplifier system can be configured to employ vacuum tubes where the first power stage comprises a first set of vacuum tubes, the second power stage comprises a second set of vacuum tubes, and the power stage drive subsystem can comprise a set of vacuum tubes (e.g., dual triode pair of tubes or a tube pair of independent triodes). The first set of vacuum tubes are dissimilar in operating characteristics and audio output characteristics than the operating characteristics and audio output characteristics of the second set of vacuum tubes. The dissimilar impedance characteristics of the first audio power stage of vacuum tubes and the second audio power stage of vacuum tubes are maintained in a half power mode.

In another embodiment, there is disclosed a first audio power stage which outputs first audio output characteristics and a second audio power stage which outputs second audio output characteristics; a power stage drive subsystem which drives the first audio power stage to output the first audio output characteristics, and drives the second audio power stage to output the second audio output characteristics, wherein the power stage drive subsystem drives the first audio power stage to output the first audio output characteristics, which first audio output characteristics are inherent to first audio power components of the first audio power stage, and drives the second audio power stage to output the second audio output characteristics, which second audio output characteristics are inherent to second audio power components of the second audio power stage; and, an audio output transformer, the first audio output characteristics and the second audio output characteristics output via primaries of the audio output transformer. The inherent first audio output characteristics are output via a first primary of the audio output transformer, and the inherent second audio output characteristics are output via a second primary of the output transformer.

The first power stage comprises a first set of vacuum tubes, the second power stage comprises a second set of vacuum tubes, and the power stage drive subsystem comprises vacuum tubes, wherein the first set of tubes are dissimilar in inherent operating characteristics and audio output characteristics than the inherent operating characteristics and audio output characteristics of the second set of vacuum tubes. The audio output transformer is configured to output the inherent first audio output characteristics via a first primary of the audio output transformer and to output the inherent second audio output characteristics via a second primary of the audio output transformer. The power stage drive subsystem is configured for dissimilar coupling of the first audio power stage and the second audio power stage, where the first audio power stage operates on a bias voltage source different than a bias voltage source of the second audio power stage.

In yet another embodiment, there is disclosed an audio amplifier method, comprising: receiving a first audio power stage which generates first inherent audio output characteristics, and a second audio power stage which generates second inherent audio output characteristics; receiving a power stage drive subsystem which drives the first audio power stage to output the first inherent audio output characteristics, and which drives the second audio power stage to output the second inherent audio output characteristics, the first inherent audio output characteristics are different than the second inherent audio output characteristics; and, outputting the first inherent audio output characteristics and the second inherent audio output characteristics via isolated primaries of a single audio output transformer, wherein the isolated primaries of a single audio output transformer are identical and matched to the respective power stages.

The audio amplifier method can further comprise outputting the first inherent audio output characteristics via a first primary of the single audio output transformer, and outputting the second inherent audio output characteristics via a second primary of the single output transformer. The audio amplifier method can further comprise configuring the power stage drive subsystem for dissimilar coupling of the first audio power stage and the second audio power stage, and driving the first audio power stage with a bias voltage source different than a bias voltage source of the second audio power stage.

The audio amplifier method, wherein the first power stage comprises a first set of vacuum tubes, the second power stage comprises a second set of vacuum tubes, and the power stage drive subsystem comprises vacuum tubes, the first set of vacuum tubes are dissimilar from the second set of vacuum tubes.

The method can further comprise configuring the first power stage as a first set of vacuum tubes, and the second power stage as a second set of vacuum tubes, and configuring the power stage drive subsystem as a third set of vacuum tubes, wherein the operating and output characteristics of first set of vacuum tubes are different than the operating and output characteristics of the second set of vacuum tubes.

The audio amplifier method can further comprise combining dissimilar impedance characteristics of a first vacuum tube power stage and a second vacuum tube power stage, and maintaining a matched impedance in the first power stage when the second power stage is powered off.

The audio amplifier method can further comprise coupling the first audio power stage to the power stage drive subsystem via a first coupling network, coupling the second audio power stage to the power stage drive subsystem via a second coupling network, and outputting the output characteristics of the first audio power stage to a first center-tapped primary of the output transformer and the output characteristics of the second audio power stage to a second center-tapped primary of the output transformer.

To the accomplishment of the foregoing and related ends, certain illustrative aspects are described herein in connection with the following description and the annexed drawings. These aspects are indicative of the various ways in which the principles disclosed herein can be practiced and all aspects and equivalents thereof are intended to be within the scope of the claimed subject matter. Other advantages and novel features will become apparent from the following detailed description when considered in conjunction with the drawings.

### BRIEF DESCRIPTION OF THE DRAWINGS

FIG. 1 illustrates an audio amplifier system in accordance with a disclosed embodiment.

FIG. 2 illustrates a detailed embodiment of a dual primary multi-coupled output amplifier system in accordance with a disclosed embodiment.

FIG. 3 illustrates an audio amplifier system with feedback in accordance with a disclosed embodiment.

FIG. 4 illustrates a detailed diagram of a dual primary multi-coupled output amplifier system with output feedback to the input inverter subsystem in accordance with a disclosed embodiment.

FIG. 5 illustrates an audio amplifier method in accordance with a disclosed embodiment.

FIG. 6 illustrates an alternative audio amplifier method in accordance with a disclosed embodiment.

### DETAILED DESCRIPTION

The disclosed architecture defines improvements in the area of component design which not only meet the needs of a wide variety of users, but also the most discerning musicians who have the ability to audibly detect the most subtle desirable tonal artifacts.

The disclosed dual primary multi-coupled output audio amplifier architecture employs a technique which offers a power-tube combining scenario that avoids the conventional “power tube switching” approach by “combining” power tube characteristics using dissimilar tubes that can be operated to co-exist with a single output transformer (of multiple (e.g., two) primary windings (e.g., identical)).

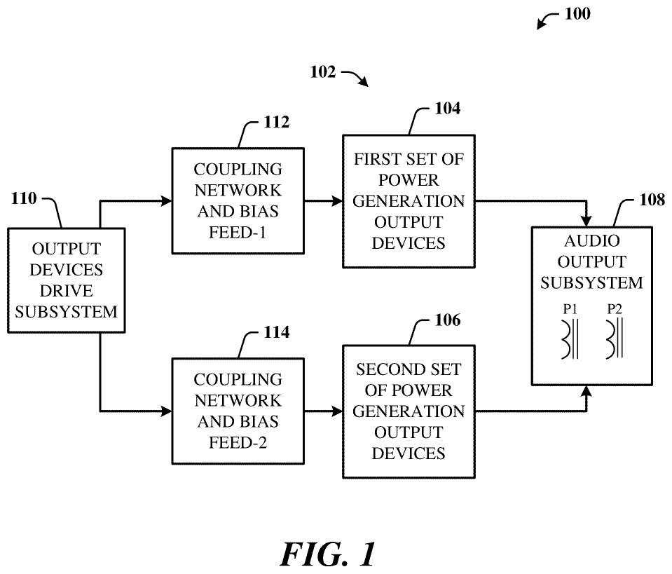

FIG. 1 illustrates an audio amplifier system 100 in accordance with the disclosed architecture. The system 100 can include an (output) power generation subsystem 102 comprising a first set of electronic power generation output devices 104 (also referred to as a first set of power output devices 104) and a second set of electronic power generation output devices 106 (also referred to as a second set of power output devices 106).

The first set of power output devices 104 can be configured to output a first set of audio characteristics at a first level of power, and the second set of power output devices 106 can be configured to output a second set of audio characteristics at a second level of power. The first set of power output devices 104 and second set of power output devices 106 drive (deliver power) to an audio output load (e.g., one or more speakers or other type(s) of audio output manipulation device or chassis) connected to an audio output subsystem 108.

The audio output subsystem 108 can be an audio transformer of two primary windings: a first primary winding P1 and a second primary winding P2. More specifically, the audio transformer can be a bifilar design, where the electromagnetic coil utilizes two closely-spaced wires, isolated from each other, to function as two independent parallel coils. As employed here, the parallel coils are wound and wired as primaries. The first primary P1 is matched and dedicated to one pair of power output devices (e.g., devices 106), and a second primary P2 is matched and dedicated to a second pair of power output devices (e.g., devices 104). It can be the case that the windings are wound such that current flows in the same direction (as in this embodiment).

The first set of electronic power generation output devices 104 can be connected to deliver output to the second primary winding P2, and the second set of electronic power generation output devices 106 can deliver output to the first primary winding P1. The two independent device stages (104 and 106) are utilized to drive separate sets of power devices (104 and 106, e.g., power tubes). Ultimately, the power devices outputs are blended together in the output transformer (audio output subsystem 108) via the dual primary windings (P1 and P2). In other words, two independent drive stages are utilized to drive separate sets of power tubes, which are ultimately blended together in the output transformer via the dual primary windings.

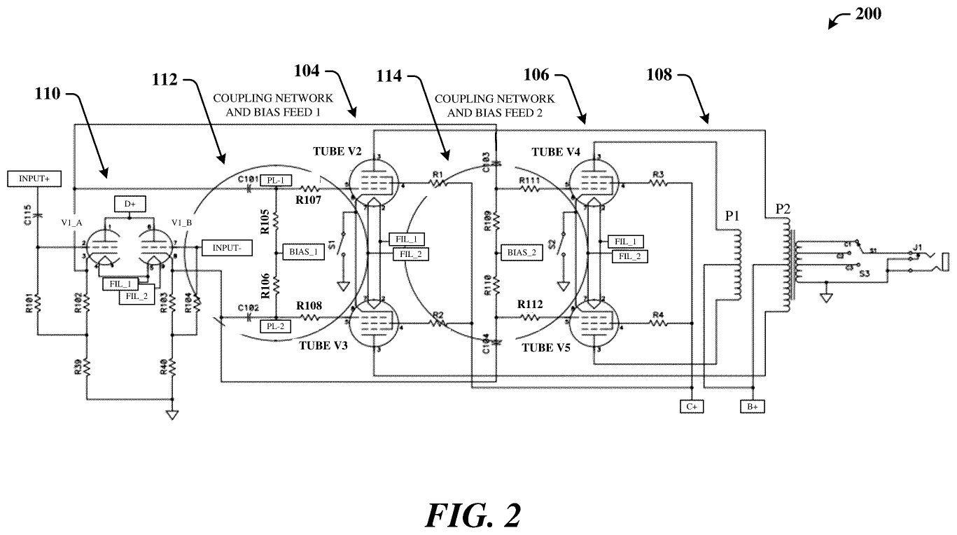

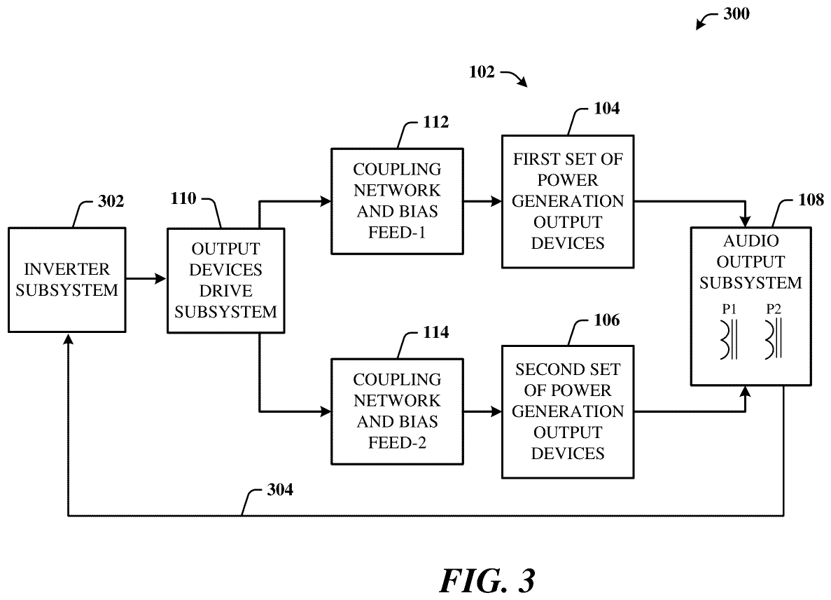

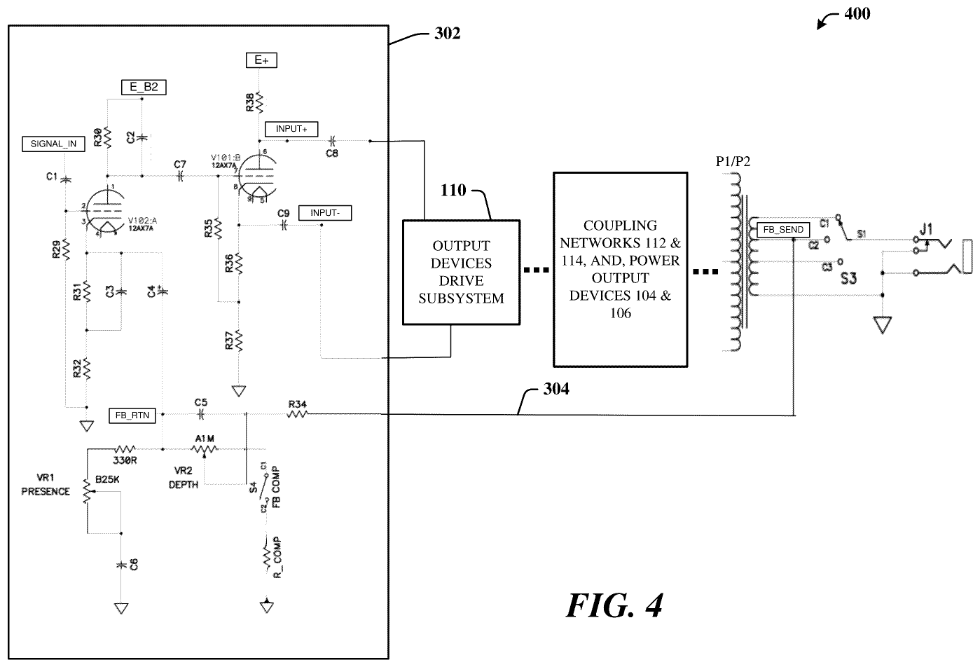

An output device drive subsystem 110 (in the form of a voltage follower which provides a low source impedance to the coupling network and bias feed 112 and 114) connects to the first set of power output devices 104 and the second set of power output devices 106. (While not illustrated in FIG. 1 and FIG. 2, but included in FIG. 3 and FIG. 4, the inverter stage can provide additional capabilities and effects.)

The output device drive subsystem 110 can be configured to bias the first set of power output devices 104 to derive (cause generation of) the first set of audio characteristics at the first level of power, and configured to bias the second set of power output devices 106 to derive (cause generation of) the second set of audio characteristics at the second level of power.

In one embodiment, the first set of audio characteristics can be output via the second primary winding P2, and the second set of audio characteristics can be output via the first primary winding P1, where the first primary winding P1 and the second primary winding P2 are isolated primary windings of the same transformer. The second transformer primary winding P2 can be matched to the first set of power output devices, and the first transformer primary winding P1 can be matched to the second set of power output devices. Alternatively, the second transformer primary winding P2 can be matched to the second set of power output devices, and the first transformer primary winding P1 can be matched to the first set of power output devices.

The output device drive subsystem 110 connects to the first set of power output devices 104 via a first coupling network and bias feed subsystem 112, and the output device drive subsystem 110 connects to the second set of power output devices 106 via a second coupling network and bias feed subsystem 114.

The output device drive subsystem 110 shown in the disclosed amplifier architecture can be customized for a specific dissimilar coupling. Accordingly, features of the drive subsystem 110 and the transformer output subsystem 108 design provide desirable and unique characteristics in the audio amplifier. For example, the load line of each tube type follows a slightly different trajectory, so the dissimilar coupling enables each pair of power tubes to react to their own dedicated bias voltage source, which assists in the optimization of the behavior of each tube pair. This is a true blending of technical designs in the output transformer and tube operation characteristics.

The first and second sets of power output devices (104 and 106) and output devices drive subsystem 110 can employ vacuum tubes; the vacuum tubes of first output tube subsystem 104 and the vacuum tubes of the second output tube subsystem 106 biased and driven according to the device drive subsystem 110.

The first set of power output devices 104 and the second set of power output devices 106 can connect to the output device drive subsystem 110 using different operational parameters to cause a dissimilar coupling which causes generation of the first set of audio characteristics and generation of the second set of audio characteristics at the amplifier output (e.g., output subsystem 108).

Removal of the power to one set of power output devices is ineffectual to the operation of the other set of power output devices. Thus, removal of the power to one set of power output devices is ineffectual in changing the impedance matching of the other set of power output devices.

An audio amplifier system 100 is disclosed comprising, a first audio power stage (e.g., the devices 104 and feed system 112) which outputs first audio output characteristics and a second audio power stage (e.g., the devices 106 and feed system 114) which outputs second audio output characteristics. The output devices drive subsystem 110 (also referred to herein as the power stage drive subsystem) drives the first audio power stage to output the first audio output characteristics, and drives the second audio power stage to output the second audio output characteristics. The audio output transformer of the system 108 enable output of the first audio output characteristics and the second audio output characteristics via primaries (e.g., at least one of the primaries P1 or P2) of the audio output transformer.

The output devices drive subsystem 110 drives the first audio power stage to output the first audio output characteristics, which first audio output characteristics are inherent to first audio power components of the first audio power stage, and drives the second audio power stage to output the second audio output characteristics, which second audio output characteristics are inherent to second audio power components of the second audio power stage.

The inherent first audio output characteristics are output via a first primary (e.g., P1) of the audio output transformer (of the output subsystem 108), and the inherent second audio output characteristics are output via a second primary (e.g., P2) of the output transformer (of the output subsystem 108).

The first power stage can comprise a first set of vacuum tubes, the second power stage can comprise a second set of vacuum tubes, and the output devices drive subsystem 110 can comprise vacuum tubes. The first set of tubes (in the power generation devices 104) can be dissimilar in operating characteristics and audio output characteristics than the operating characteristics and audio output characteristics of the second set of vacuum tubes (in the power generation devices 106).

The inherent first audio output characteristics are different than the inherent second audio output characteristics. The audio output transformer (of subsystem 108) is configured to output the inherent first audio output characteristics via a first primary (P1) of the audio output transformer and to output the inherent second audio output characteristics via a second primary (p2) of the audio output transformer (od subsystem 108).

The audio amplifier system 100 can further comprise the output devices drive subsystem 110 configured for dissimilar coupling of the first audio power stage and the second audio power stage, wherein the first audio power stage operates on a bias voltage source different than a bias voltage source of the second audio power stage. The matched impedance in the first power stage can be maintained when the second power stage is powered off. Additionally, the dissimilar impedance characteristics of the first audio power stage of vacuum tubes and the second audio power stage of vacuum tubes can be maintained in a half power mode.

FIG. 2 illustrates a detailed embodiment of a dual primary multi-coupled output amplifier system 200 in accordance with the disclosed architecture. In this embodiment, the system 200 is implemented using vacuum tube technology.

The description begins with the output devices drive subsystem 110, to the first coupling network and bias feed 112, to the first set of power generation devices 104, to the second coupling network and bias feed 114, to the second set of power generation devices 106, followed by the audio output subsystem 108.

The output devices drive subsystem 110 can be a double triode tube arrangement, for example, such as can be obtained using a 12AT7 double triode tube (denoted as first tube V1_A, and second tube V1_B). Respective pins 1 and 6 of the twin triodes are the plates outputting a plate voltage of D+. Pins 2 and 7 are the grid control pins for controlling the plate outputs via INPUT+ and INPUT−, respectively.

The INPUT+ node connects to a capacitor C115 (anode) and then from the cathode to grid pin 2, and to a first resistor network between the grid pin 2, cathode pin 3, and ground. The first resistor network of the first triode tube V1-A comprises resistors R101, R102, and R39 (one side to ground), with one side of R101 connected to a node common to R102 and R39 (side opposite of ground). Resistor R102 connects to cathode pin 3 of the first tube V1_A.

Similarly, node INPUT− connects to grid pin 7 of the second triode tube V1_B, and to second resistor network between the grid pin 7, cathode pin 8, and the ground. The second resistor network of the second triode tube comprises resistors R103, R104, and R40 (one side to ground), with R104 connected on one side to INPUT− and on other side to a node common to R103 and R40. Resistor R103 connects to the cathode pin 8 of the second tube V1_B and to R40 (the other side, not ground).

The filament current FIL_1 at heater pin 4 of V1_A and heater pin 5 of V1_B, and filament current FIL_2 of pin 9, are subsequently connected to the heater pins of the first set of power generator devices 104 and the second set of power generator devices 106. Thus, the electron flow from the cathodes of the twin triodes (V1_A and V1_B) and the two sets of twin pentodes are based on the same heater currents (FIL_1 and FIL_2) of the output devices drive subsystem 110.

The cathode voltage at pin 3 (of V1_A) and cathode voltage at pin 8 (of V1_B) are then connected to the two separate coupling networks: the first coupling network 112 and the second coupling network 114.

The first coupling network 112 can be defined as comprising a system of circuit elements and nodes: capacitors C101 and C102, resistors R1 and R2, nodes PL-1 and PL-2, and bias node BIAS_1. Node PL-1 is the same junction as C101, R105, and R107. Node PL-2 is the same junction point as C102, R106, and R108. The BIAS_1 node is the same junction point between resistors R105 and R106.

The first coupling network 112 interfaces to the first set of power generation devices 104 (also referred to herein as a first power stage and first audio power stage, and designated as including pentode tubes V2 and V3), which can be pentodes such as KT88 tubes. The first coupling network 112 interfaces to tube V2 by way of resistor R107 connecting to the pin 5 control grid, and interfaces to tube V3 by way of resistor R108 connecting to the pin 5 control grid.

The plate pins 3 of tubes V2 and V3 each connect to opposite ends of the second winding P2 of the primary winding of the output transformer in the audio output subsystem 108. In other words, plate pin 3 of tube V2 connects to one side of the primary winding P2 and plate pin 3 of tube V3 connects to the other side of the primary winding P2.

Resistors R1 and R2 are screen grid resistors such that R1 connects to screen grid pin 4 of tube V2 and R2 connects to screen grid pin 4 of tube V3. The side of R1 and R2 away from the tubes V2 and V3 connect at a single node and can be controlled by a screen grid voltage (or current) C+, which is the same voltage (or current) applied to respective screen grid pins 4 of the second set of power generation devices 106.

Switch S1 connects to both the cathode pins 8 of the tubes V2 and V3, and once closed, grounds the cathodes of V2 and V3. Opening switch S1 disables the first set of power generation devices 104 from operation entirely, leaving the second set of power generation devices 106 operating (since switch S2 is closed) to provide the desired output and associated second set of audio characteristics.

Heater pins 2 of tubes V2 and V3 are interconnected and receive control current of FIL_1. Similarly, heater pins 7 of tubes V2 and V3 are interconnected and receive control current of FIL_2. Screen grid pins 4 of the tubes V2 and V3 connect respectively to resistor R1 and resistor R2 of the first coupling network 112. That is, screen grid pin 4 of the tube V2 connects to R1 of the first coupling network 112 and screen grid pin 4 of the tube V3 connects to R2 of the first coupling network 112. Additionally, resistor R1 and resistor R2 both connect to voltage node C+. In this particular embodiment, the suppressor grid at pin 1 of either or both of the tubes V2 and V3, is not utilized, but can be considered for other desired effects.

The second coupling network 114 can be defined as comprising a system of circuit elements and nodes: capacitors C103 and C104, resistors R109, R110, R111, R112, resistors R3, R4, and bias node BIAS_2. The BIAS_2 node is the same junction point between resistors R109 and R110.

The second coupling network 114 interfaces to the second set of power generation devices 106 (also designated as including pentode tubes V4 and V5), which can be pentodes such as KT88 tubes. The second coupling network 114 interfaces to tube V4 by way of capacitor C103 and resistor R111 connecting to the pin 5 control grid, and interfaces to tube V5 by way of capacitor C104 and resistor R112 connecting to the pin 5 control grid.

The plate pins 3 of tubes V4 and V5 each connect to opposite ends of the first primary winding P1 of the output transformer of the audio output subsystem 108. In other words, plate pin 3 of tube V4 connects to one side of the first primary winding P1 and plate pin 3 of tube V5 connects to the other side of the first primary winding P1.

Resistors R3 and R4 are screen grid resistors such that R3 connects to screen grid pin 4 of tube V4 and R4 connects to screen grid pin 4 of tube V5. The sides (or ends) of R3 and R4 away from the tubes V4 and V5 connect at a single node and can be controlled by a screen grid voltage (or current) C+, which is the same voltage (or current) applied to respective screen grid pins 4 (through R1 and R2) of the first set of power generation devices 104.

Switch S2 connects to both the cathode pins 8 of the tubes V4 and V5, and once closed, grounds the cathodes of tubes V4 and V5. Essentially, opening switch S2 disables the second set of power generation devices 106 from operation entirely, leaving the first set 104 operating (since Switch S1 is closed) to provide the desired output and associated second set of audio characteristics.

Heater pins 2 of tubes V4 and V5 are interconnected and receive filament current of FIL_1. Similarly, heater pins 7 of tubes V4 and V5 are interconnected and receive filament current of FIL_2. Screen grid pins 4 of the tubes V4 and V5 connect respectively to R3 and R4 of the second coupling network 114. That is, screen grid pin 4 of the tube V4 connects to R3 of the second coupling network 114 to voltage C+, and screen grid pin 4 of the tube V5 connects to R4 of the second coupling network 114 to voltage C+. In this particular embodiment, the suppressor grid at pin 1 of either or both of the tubes V4 and V5, is either connected internally to pin 8 or externally via pin 1 and pin 8 of their respective tube sockets.

In one embodiment, circuit element values can be the following: C115 0.22 uF 400V, R101 and R104 can be 470KΩ, R102 and R103 can be 1KΩ, R39 and R40 can be 22KΩ (rated at 2 watts), C101 and C102 can be 0.33 uF (rated at 400V), R105 and R106 can be 100KΩ, R107 and R108 can be 4.7KΩ, R1 and R2 can be 1KΩ (rated at 5 watts), R109 and R110 can be 220KΩ, R111 and R112 can be 4.7 KΩ, C103 and C104 can be 0.1 uF (rated at 400V), R3 and R4 can be 1 KΩ (rated at 5 watts), and switches S1 and S2 can be standard single pole-single throw switches (e.g., rotary switches, toggle switches, etc.).

The first primary winding (P1) of the output transformer and second primary winding (P2) of the output transformer can both be center tapped, with a voltage B+ at the center tap of the second primary P2 and at the center tap of the first primary P1. On the other side of the primaries (P1 and P2) can be taps for the most common speaker loads such as 2 ohms, 4 ohms, 8 ohms, and 16 ohms (represented by switch positions C1, C2, C3 of a rotary switch S3), and accessible using an output jack J1.

An additional benefit of dual primaries: each transformer primary (P1 and P2) remains matched to the respective tube pairs (primary P1 is matched to power generation devices 106, and primary P2 is matched to power generation devices 104. Turning off one tube pair (e.g., devices 104) does not affect operation of the remaining tube pair (e.g., devices 106). The remaining tube pair stays impedance-matched and does not exhibit an unpleasant crossover distortion, leading to a tonal shift of an impedance mismatch.

Screen grid voltage at pins 4 of the power pentode tubes (e.g., KT88) is at C+, control grid voltage at pins 5 of the power pentode tubes is the BIAS_2 voltage. The power stage drive subsystem 110 can utilize a 12AT7 double-triode vacuum tube (“tube”). Two power tubes (e.g., EL34 pentode tubes) can be used in the power output subsystem. Two power tubes (e.g., KT88 beam pentode tubes) can be used in the power output subsystem.

FIG. 3 illustrates an audio amplifier system 300 with feedback to an inverter subsystem 302 in accordance with a disclosed embodiment. The phase inverter subsystem 302, when coupled with an input gain stage (the output device drive subsystem 110) includes a user-adjustable (variable) negative feedback path 304 from a speaker output terminal (of the audio output subsystem 108). This feedback capability can further enable varying of the behavior of the system 300. Negative feedback loop 304 gain is dependent upon total system gain. Since the total system gain and effective output impedance is determined by the number and types of output devices 104 and 106, feedback loop 304 gain is modified for each operational mode in order to stabilize system gain, or allow further user manipulation to achieve a result desirable to the user.

FIG. 4 illustrates a detailed diagram of a dual primary multi-coupled output amplifier system 400 with output feedback to the input inverter subsystem 302, in accordance with a disclosed embodiment. The focus is on the inverter subsystem 302, the output subsystem 108, and the feedback path 304. (Other system components are drawn in an abbreviated format after having been described elsewhere herein. For example, the drive subsystem 110, power output devices 104 and 106, and coupling networks 112 and 114, have been described and illustrated previously.)

In this illustration, the inverter subsystem 302, the feedback signa(s) 304 is sent from a Feedback_Send node on the C2 node of the S3 output switch. Although depicted as connected to the C2 node of switch S3, it can be that feedback 304 can be obtained from any one of the switch S3 nodes, such as from C1, C2, or C3. Additionally, as indicated, the feedback signal(s) 304 are obtained from the isolated P2 winding. However, although not shown, the feedback signal(s) 304 can be obtained from the isolated P1 winding, where any one or more of switch nodes of a different switch are employed.

The inverter subsystem 302 illustrates an arrangement of circuit components (e.g., resistors, capacitors, variable resistors (e.g., for VR1 Presence effects, VR2 for Depth effects, etc.), switches (e.g., Switch S4 for feedback comp), and vacuum tubes (e.g., 12AX7A). Ultimately, the inverter subsystem 302 (inverter stage) drives the output device drive subsystem 110.

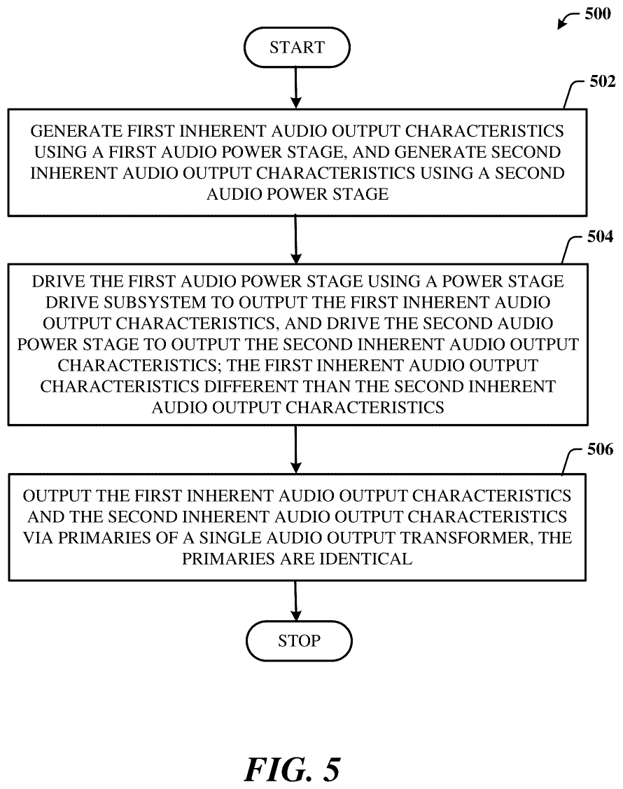

FIG. 5 illustrates an audio amplifier method 500 in accordance with the disclosed architecture. At 502, driving a first audio power stage to generate first inherent audio output characteristics. At 504, driving a second audio power stage to generate second inherent audio output characteristics. At 506, outputting first inherent audio output characteristics and the second inherent audio output characteristics via isolated primaries of a single audio output transformer.

The method can further comprise driving the first audio power stage using the power stage drive subsystem to output the first audio output characteristics, which first audio output characteristics are inherent to first audio power components of the first audio power stage; and driving the second audio power stage using the power stage drive subsystem to output the second audio output characteristics, which second audio output characteristics are inherent to second audio power components of the second audio power stage.

The method can further comprise outputting the inherent first audio output characteristics via a first primary of the single audio output transformer, and outputting the inherent second audio output characteristics via a second primary of the single output transformer.

The first power stage comprises a first set of vacuum tubes, the second power stage comprises a second set of vacuum tubes, and the power stage drive subsystem can comprise vacuum tubes. The first set of tubes are dissimilar (different in biasing and operating characteristics) from the second set of vacuum tubes. The inherent first audio output characteristics are different than the inherent second audio output characteristics. The isolated primaries of the single audio output transformer are matched to the respective power stages and identical.

The power stage drive subsystem is configured for dissimilar coupling of the first audio power stage and the second audio power stage, where the first audio power stage operates on a bias voltage source different than a bias voltage source of the second audio power stage. The audio amplifier system is configured to maintain a matched impedance in the first power stage when the second power stage is powered off. The audio amplifier provides the capability to combine dissimilar impedance characteristics of a first vacuum tube power stage and a second vacuum tube power stage, while maintaining a matched impedance in a half power mode.

The method can further comprise coupling the first audio power stage to the power stage drive subsystem via a first coupling network, coupling the second audio power stage to the power stage drive subsystem via a second coupling network, and outputting the output characteristics of the first audio power stage to a first center-tapped primary of the output transformer and outputting the output characteristics of the second audio power stage to a second center-tapped primary of the output transformer.

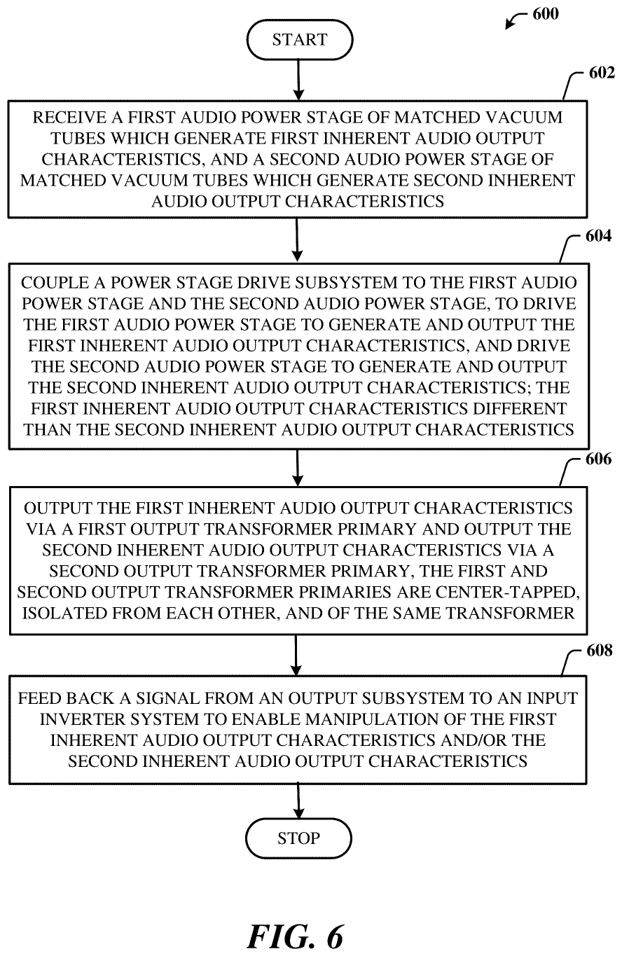

FIG. 6 illustrates an audio amplifier method 400 in accordance with the disclosed architecture. At 602, a first audio power stage of matched vacuum tubes is received and which generates first inherent audio output characteristics, and a second audio power stage of matched vacuum tubes is received and which generate second inherent audio output characteristics.

At 604, a power stage drive subsystem is coupled to the first audio power stage and the second audio power stage, to drive the first audio power stage to generate and output the first inherent audio output characteristics, and drive the second audio power stage to generate and output the second inherent audio output characteristics; the first inherent audio output characteristics different than the second inherent audio output characteristics.

At 606, outputting the first inherent audio output characteristics via a first output transformer primary and outputting the second inherent audio output characteristics via a second output transformer primary, the first and second output transformer primaries are isolated from each other, center-tapped, and of the same transformer.

At 608, a signal is fed back from an output subsystem (e.g., transformer subsystem) to an input inverter system to enable manipulation of the first inherent audio output characteristics and/or the second inherent audio output characteristics.

What has been described above includes examples of the disclosed architecture. It is, of course, not possible to describe every conceivable combination of components and/or methodologies, but one of ordinary skill in the art may recognize that many further combinations and permutations are possible. Accordingly, the novel architecture is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. An audio amplifier system, comprising:
a first power stage which outputs first audio output characteristics;
a second power stage which outputs second audio output characteristics;
a power stage drive subsystem which drives the first power stage to output the first audio output characteristics, and drives the second power stage to output the second audio output characteristics; and
an audio output transformer, the first audio output characteristics and the second audio output characteristics output via isolated primaries of the audio output transformer.

2. The audio amplifier system of claim 1, wherein the power stage drive subsystem drives the first power stage to output the first audio output characteristics, which first audio output characteristics are inherent to power components of the first power stage, and drives the second power stage to output the second audio output characteristics, which second audio output characteristics are inherent to power components of the second power stage.

3. The audio amplifier system of claim 2, wherein the audio output transformer is configured to output the inherent first audio output characteristics via a first primary winding and to output the inherent second audio output characteristics via a second primary winding.

4. The audio amplifier system of claim 2, wherein the inherent first audio output characteristics are different than the inherent second audio output characteristics.

5. The audio amplifier system of claim 1, wherein the first power stage comprises a first set of vacuum tubes, the second power stage comprises a second set of vacuum tubes, and the output device drive subsystem comprises drive vacuum tubes.

6. The audio amplifier system of claim 5, wherein the first set of vacuum tubes are dissimilar in operating characteristics and audio output characteristics than the operating characteristics and audio output characteristics of the second set of vacuum tubes.

7. The audio amplifier system of claim 6, wherein dissimilar impedance characteristics of at least one of the first power stage of vacuum tubes or the second power stage of vacuum tubes are maintained to approximate a half power mode.

8. The audio amplifier system of claim 1, wherein the output device drive subsystem is configured for dissimilar coupling of the first power stage and the second power stage, wherein the first power stage operates on a bias voltage source different than a bias voltage source of the second power stage.

9. The audio amplifier system of claim 1, wherein a matched impedance in one power stage is maintained when another power stage is powered off.

10. The audio amplifier system of claim 1, further comprising an inverter subsystem connected to the power stage drive subsystem to drive the first and second power stages and receive a feedback signal which enables control over output effects.

11. An audio amplifier system, comprising:
an inverter subsystem connected to a power stage drive subsystem to drive first and second power stages and receive a feedback signal from an output transformer which enables control over output effects, the first audio power stage outputs first audio output characteristics, and a second audio power stage which outputs second audio output characteristics; and
a power stage drive subsystem which drives the first audio power stage to output the first audio output characteristics, and drives the second audio power stage to output the second audio output characteristics, which first audio output characteristics are inherent to power components of the first audio power stage, and which second audio output characteristics are inherent to power components of the second audio power stage; wherein the first audio output characteristics and the second audio output characteristics are output via isolated primaries of the audio output transformer.

12. The audio amplifier system of claim 11, wherein the inherent first audio output characteristics are output via a second primary of the audio output transformer, and the inherent second audio output characteristics are output via a first primary of the output transformer.

13. The audio amplifier system of claim 11, wherein the first audio power stage comprises a first set of vacuum tubes, the second audio power stage comprises a second set of vacuum tubes, and the output devices drive subsystem comprises drive vacuum tubes, wherein the first set of vacuum tubes are dissimilar in inherent operating characteristics and audio output characteristics than the inherent operating characteristics and audio output characteristics of the second set of vacuum tubes.

14. The audio amplifier system of claim 11, wherein the audio output transformer is configured to output the inherent first audio output characteristics via a second primary of the audio output transformer and to output the inherent second audio output characteristics via a first primary of the audio output transformer.

15. The audio amplifier system of claim 11, wherein the output devices drive subsystem is configured for dissimilar coupling of the first audio power stage and the second audio power stage, where the first audio power stage operates on a bias voltage source different than a bias voltage source of the second audio power stage.

16. An audio amplifier method, comprising:
driving a first audio power stage with to output first inherent audio output characteristics;
driving a second audio power stage to output the second inherent audio output characteristics, the first inherent audio output characteristics are different than the second inherent audio output characteristics; and
outputting the first inherent audio output characteristics and the second inherent audio output characteristics via isolated primaries of an audio output transformer.

17. The audio amplifier method of claim 16, further comprising outputting the first inherent audio output characteristics via a second primary of the audio output transformer, and outputting the second inherent audio output characteristics via a first primary of the audio output transformer.

18. The audio amplifier method of claim 16, further comprising configuring the power stage drive subsystem for dissimilar coupling between the first audio power stage and the second audio power stage, and driving the first audio power stage with a bias voltage different than a bias voltage of the second audio power stage.

19. The audio amplifier method of claim 16, further comprising;
combining dissimilar output impedance characteristics of the first vacuum tube power stage and the second vacuum tube power stage; and
maintaining a matched impedance in the first power stage when the second power stage is powered off.

20. The audio amplifier method of claim 16, further comprising;
coupling the first audio power stage to a power stage drive subsystem via a first coupling network;
coupling the second audio power stage to the power stage drive subsystem via a second coupling network; and
outputting the first inherent output characteristics of the first audio power stage to a first center-tapped primary of the output transformer and outputting the second inherent output characteristics of the second audio power stage to a second center-tapped primary of the output transformer.
